(19) United States
(12) Patent Application Publication
(10) Pub. No.: US 2025/0248238 A1
(43) Pub. Date: Jul. 31, 2025

(54) DISPLAY APPARATUS AND METHOD OF MANUFACTURING THE SAME

(71) Applicant: Samsung Display Co., Ltd., Yongin-si (KR)

(72) Inventors: Heesung Lim, Yongin-si (KR); Youngmoo Kwon, Yongin-si (KR)

(73) Assignee: Samsung Display Co., Ltd., Yongin-si (KR)

(21) Appl. No.: 18/944,461

(22) Filed: Nov. 12, 2024

(30) Foreign Application Priority Data
Jan. 31, 2024 (KR) 10-2024-0015185

(51) Int. Cl. H10K 59/126; H10K 59/12; H10K 59/80

(52) U.S. Cl. CPC H10K 59/126; H10K 59/1201; H10K 59/873; H10K 59/8791

(57) ABSTRACT

A display apparatus, in which the possibility of occurrence of defects may be reduced in a manufacturing process thereof, may include a display panel including a display element, an optical functional layer disposed on the display panel, a light control layer disposed on the optical functional layer, wherein the light control layer may include multiple grooves, the grooves may be respectively arranged adjacent to vertexes of the light control layer in a plan view, sides of the light control layer respectively overlap sides of the optical functional layer in a plan view, and in a plan view, the vertexes of the light control layer respectively overlap vertexes of the optical functional layer.

### CROSS-REFERENCE TO RELATED APPLICATIONS

This application claims priority under 35 U.S.C. § 119 from Korean Patent Application No. 10-2024-0015185 filed on Jan. 31, 2024 in the Korean Intellectual Property Office, the entire contents of which are incorporated herein by reference.

### BACKGROUND

### 1. Technical Field

One or more embodiments relate to a display apparatus in which the possibility of occurrence of defects in a process of manufacturing the same may be reduced, and a method of manufacturing the display apparatus.

### 2. Description of the Related Art

A cover window of a display apparatus may protect a display element of a display panel included in the display apparatus from external shock and block light so that wirings or circuits of the display panel are not visible from the outside. The cover window may be attached over the display panel by using an adhesive layer. In particular, the cover window may be pressurized after an adhesive layer formation material coated over the display panel is pre-cured. Accordingly, the cover window may be attached over the display panel by main-curing the pre-cured adhesive layer formation material.

### SUMMARY

However, in a display apparatus in the related art and a method of manufacturing the display apparatus, the pre-cured adhesive layer formation material overflows in a process of pressurizing the cover window.

One or more embodiments include a display apparatus, in which the possibility of occurrence of defects in a process of manufacturing the same may be reduced, and a method of manufacturing the display apparatus. However, these objectives are exemplary, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus may include a display panel including a display element, an optical functional layer disposed on the display panel, a light control layer disposed on the optical functional layer, wherein the light control layer may include a plurality of grooves, the plurality of grooves may be respectively arranged adjacent to vertexes of the light control layer in a plan view, sides of the light control layer may respectively overlap sides of the optical functional layer in a plan view, and in a plan view, the vertexes of the light control layer may respectively overlap vertexes of the optical functional layer.

In a plan view, the sides of the light control layer may respectively coincide with the sides of the optical functional layer, and in a plan view, the vertexes of the light control layer may respectively coincide with the vertexes of the optical functional layer.

The optical functional layer may include a first-1 side, a first-2 side, a first-3 side, and a first-4 side, the first-1 side and the first-2 side may face each other, and the first-3 side and the first-4 side may face each other and may be positioned between the first-1 side and the first-2 side, the light control layer may include a second-1 side, a second-2 side, a second-3 side, and a second-4 side, the second-1 side and the second-2 side may face each other, and the second-3 side and the second-4 side may face each other and may be positioned between the second-1side and the second-2 side, the second-1 side may coincide with the first-1 side in a plan view, the second-2 side may coincide with the first-2 side in a plan view, the second-3 side may coincide with the first-3 side in a plan view, and the second-4 side may coincide with the first-4 side in a plan view.

The optical functional layer may include a first-1 vertex provided by contact between the first-1 side and the first-3 side, a first-2 vertex provided by contact between the first-1 side and the first-4 side, a first-3 vertex provided by contact between the first-2 side and the first-3 side, and a first-4 vertex provided by contact between the first-2 side and the first-4 side, the light control layer may include a second-1 vertex provided by contact between the second-1side and the second-3 side, a second-2 vertex provided by contact between the second-1 side and the second-4 side, a second-3 vertex provided by contact between the second-2 side and the second-3 side to each other, and a second-4 vertex provided by contact between the second-2 side and the second-4 side, the second-1 vertex may coincide with the first-1 vertex in a plan view, the second-2 vertex may coincide with the first-2 vertex in a plan view, the second-3 vertex may coincide with the first-3 vertex in a plan view, and the second-4 vertex may coincide with the first-4 vertex in a plan view.

The light control layer may further include a plurality of trenches, and the plurality of trenches may be respectively arranged between ones of the plurality of grooves in a plan view.

Each of the plurality of trenches may extend along one of the sides of the light control layer.

The display apparatus may further include a control dam arranged in each of the plurality of grooves.

The control dam and the light control layer may be integral with each other.

The display apparatus may further include a cover window disposed over the display panel, and an adhesive layer disposed between the light control layer and the cover window.

The light control layer may further include a plurality of trenches, the plurality of trenches may be respectively arranged between ones of the plurality of grooves in a plan view, and the adhesive layer may fill the plurality of trenches. The optical functional layer may include a polarizing film.

According to one or more embodiments, a method of manufacturing a display apparatus may include attaching an optical functional layer to a display panel, attaching a light control layer to the optical functional layer, forming a preliminary adhesive layer by applying an adhesive layer formation material to the light control layer and irradiating the adhesive layer formation material with ultraviolet rays, arranging a cover window on the preliminary adhesive layer and pressurizing the cover window, and forming an adhesive layer by irradiating ultraviolet rays to the preliminary adhesive layer, wherein the light control layer may include a plurality of grooves, the plurality of grooves may be respectively arranged adjacent to vertexes of the light control layer in a plan view, and the attaching of the light control layer may include attaching the light control layer to the optical functional layer by using the plurality of grooves so that sides of the light control layer respectively overlap sides of the optical functional layer, and vertexes of the light control layer respectively overlap vertexes of the optical functional layer in a plan view.

The attaching of the light control layer may include attaching the light control layer to the optical functional layer by using the plurality of grooves so that the sides of the light control layer respectively coincide with the sides of the optical functional layer, and the vertexes of the light control layer respectively coincide with the vertexes of the optical functional layer in a plan view.

The optical functional layer may include a first-1 side, a first-2 side, a first-3 side, and a first-4 side, the first-1 side and the first-2 side may face each other, and the first-3 side and the first-4 side may face each other and may be positioned between the first-1 side and the first-2 side, the light control layer may include a second-1 side, a second-2 side, a second-3 side, and a second-4 side, the second-1 side and the second-2 side may face each other, and the second-3 side and the second-4 side may face each other and may be positioned between the second-1 side and the second-2 side, and the attaching of the light control layer may include attaching the light control layer to the optical functional layer by using the plurality of grooves so that the second-1 side coincides with the first-1 side in a plan view, the second-2 side coincides with the first-2 side in a plan view, the second-3 side coincides with the first-3 side in a plan view, and the second-4 side coincides with the first-4 side in a plan view.

The optical functional layer may include a first-1 vertex provided by contact between the first-1 side and the first-3 side, a first-2 vertex provided by contact between the first-1 side and the first-4 side, a first-3 vertex provided by contact between the first-2 side and the first-3 side, and a first-4 vertex provided by contact between the first-2 side and the first-4 side, the light control layer may include a second-1 vertex provided by contact between the second-1side and the second-3 side, a second-2 vertex provided by contact between the second-1 side and the second-4 side, a second-3 vertex provided by contact between the second-2 side and the second-3 side, and a second-4 vertex provided by contact between the second-2 side and the second-4 side, and the attaching of the light control layer may include attaching the light control layer to the optical functional layer by using the plurality of grooves so that the second-1 vertex coincides with the first-1 vertex in a plan view, the second-2 vertex coincides with the first-2 vertex in a plan view, the second-3 vertex coincides with the first-3 vertex in a plan view, and the second-4 vertex coincides with the first-4 vertex in a plan view.

The light control layer may further include a plurality of trenches, the plurality of trenches may be respectively arranged between ones of plurality of grooves in a plan view, and the forming of the preliminary adhesive layer may include filling the adhesive layer formation material in the plurality of trenches.

Each of the plurality of trenches may extend along one of the sides of the light control layer.

A control dam may be arranged in each of the plurality of grooves, and the forming of the preliminary adhesive layer may include filling the adhesive layer formation material in the plurality of grooves.

The control dam and the light control layer may be integral with each other.

The optical functional layer may include a polarizing film.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic plan view of a display panel of a display apparatus according to an embodiment;

FIG. 4 is schematic diagram of an equivalent circuit of a pixel included in the display panel of FIG. 3;

FIG. 5 is a schematic cross-sectional view of the display panel of FIG. 3, taken along line III-III′;

FIG. 6 is a schematic plan view of an optical functional layer of a display apparatus according to an embodiment;

FIG. 7 is a schematic plan view of a light control layer of a display apparatus according to an embodiment;

FIG. 8 is a schematic cross-sectional view of the display apparatus of FIG. 1, taken along line I-I′;

FIG. 9 is a schematic cross-sectional view of the display apparatus of FIG. 1, taken along line II-II′;

FIGS. 10 to 14 are schematic diagrams for describing a process of manufacturing a display apparatus according to an embodiment;

FIG. 15 is a schematic cross-sectional view of a portion of a display apparatus being manufactured according to a comparative example;

FIG. 16 is a schematic plan view of a light control layer of a display apparatus according to an embodiment;

FIG. 17 is a schematic cross-sectional view of the display apparatus of FIG. 16 taken along line VI-VI′;

FIG. 18 is a schematic cross-sectional view of the display apparatus of FIG. 16 taken along line VII-VII′;

FIGS. 19 to 21 are schematic diagrams for describing the cross-sectional shapes of a trench of FIG. 16;

FIGS. 22 is a schematic enlarged plan view of a portion A of the light control layer of FIG. 16;

FIG. 23 is a schematic diagram for describing the cross-sectional shapes of a groove and a control dam of FIG. 22; and

FIGS. 24 to 27 are schematic diagrams for describing a process of manufacturing a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

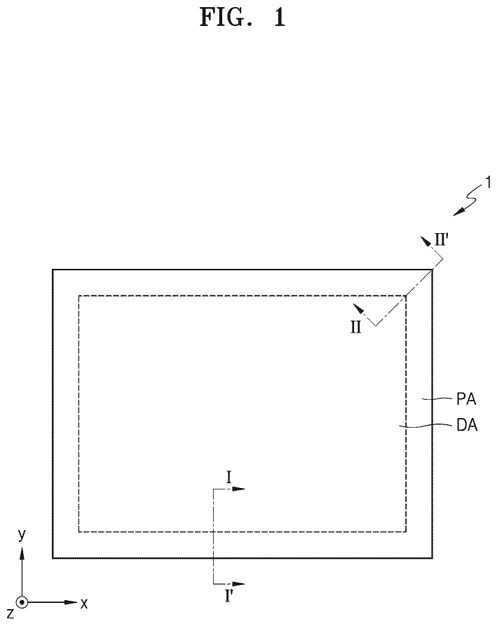

FIG. 1 is a schematic plan view of a display apparatus 1 according to an embodiment. The display apparatus 1 may be implemented as various types of electronic devices. In an embodiment, the display apparatus 1 may be a display apparatus for a vehicle, but the display apparatus 1 of the disclosure is not limited thereto.

As shown in FIG. 1, the display apparatus 1 may include a display area DA and a peripheral area PA surrounding the display area DA. The display apparatus 1 may provide an image through an array of multiple pixels, which may be two-dimensionally arranged in the display area DA.

Each of the pixels of the display apparatus 1 may be an area capable of emitting a certain color of light, and the display apparatus 1 may provide an image by using light emitted by the pixels. For example, each pixel may emit red, green, or blue light.

The display area DA may have a polygonal shape including a quadrangular shape, as shown in FIG. 1. For example, the display area DA may have a rectangular shape in which a horizontal length may be greater than a vertical length, a rectangular shape in which a horizontal length may be less than a vertical length, or a square shape. As another example, the display area DA may have various shapes, such as an oval shape or a circular shape.

The peripheral area PA may be a non-display area that does not provide an image and may entirely surround the display area DA. A driving circuit for providing an electrical signal to a display clement corresponding to a pixel or a power line for providing power to the display clement corresponding to the pixel may be arranged in the peripheral area PA.

Hereinafter, an organic light-emitting display apparatus may be described as an example of the display apparatus 1 according to an embodiment. However, the display apparatus 1 in the disclosure is not limited thereto. In an embodiment, the display apparatus 1 of the disclosure may be a display apparatus such as an inorganic light-emitting display apparatus or an inorganic electroluminescence (EL) display apparatus, or a quantum dot light-emitting display apparatus. For example, an emission layer of a display element included in the display apparatus 1 may include an organic material or an inorganic material. The display apparatus 1 may also include an emission layer and a quantum dot positioned on a path of light emitted by the emission layer. In an embodiment, the display apparatus 1 of the disclosure may be a liquid-crystal display apparatus.

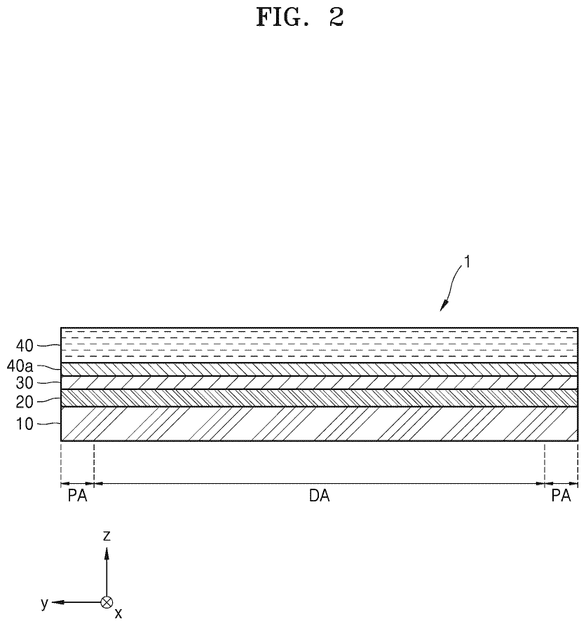

FIG. 2 is a schematic cross-sectional view of the display apparatus 1 according to an embodiment. As shown in FIG. 2, the display apparatus 1 may include a display panel 10, an optical functional layer 20, a light control layer 30, a cover window 40, and an adhesive layer 40a. As needed, the display apparatus 1 may further include various components in addition to the configuration shown in FIG. 2.

The display panel 10 may be disposed below the cover window 40. The display panel 10 may display an image. For example, an image provided by the display apparatus 1 may be implemented by the display panel 10. The display panel 10 may include multiple display elements, and each of the display elements may emit red, green, or blue light. Accordingly, the display panel 10 may display an image through light emitted by the display elements. An image displayed by the display panel 10 may be provided to a user through the cover window 40, which may be transparent.

The cover window 40 may be disposed over the upper surface of the display panel 10 (in a +z direction). Here, the ‘upper surface’ of the display panel 10 may be defined as a surface facing a direction in which the display panel 10 provides an image. According to an embodiment, the cover window 40 may be arranged to cover the upper surface of the display panel 10. The cover window 40 may protect the upper surface of the display panel 10. the cover window 40 forms the exterior of the display apparatus 1, the cover window 40 may include a substantially flat surface and a curved surface, which correspond to the shape of the display apparatus 1. The cover window 40 may have a high transmittance to transmit light emitted from the display panel 10, and may have a thin thickness to reduce the weight of the display apparatus 1. The cover window 40 may have strong strength and hardness to protect the display panel 10 from external impact.

The optical functional layer 20 may be arranged between the display panel 10 and the cover window 40. In particular, the optical functional layer 20 may be disposed above the display panel 10. The optical functional layer 20 may reduce the reflectance of light (e.g., external light) incident from the outside toward the display panel 10. Accordingly, the optical functional layer 20 may improve the color purity of light emitted from the display panel 10. The optical functional layer 20 may include a polarizing film including a retarder and a polarizer. The retarder may include a λ/2 retarder and/or a λ/4 retarder. Although not illustrated in the drawing, an adhesive member may be between the optical functional layer 20 and the display panel 10. The adhesive member may include at least one of an optical clear resin (OCR), an optical clear adhesive (OCA), and a pressure sensitive adhesive (PSA). The adhesive member may couple the optical functional layer 20 and the display panel 10 to each other.

The light control layer 30 may be between the optical functional layer 20 and the cover window 40. In particular, the light control layer 30 may be disposed on the optical functional layer 20. Light emitted with a certain angle or more to the upper side or lower side in a direction perpendicular to the cover window 40 may be blocked by a viewing angle control pattern (not shown) of the light control layer 30. In particular, in case that the display apparatus 1 is a display apparatus for a vehicle, the light control layer 30 may be a light control film that blocks light toward the front glass (e.g., a windshield) of the vehicle among light emitted from the display apparatus 1. The light control layer 30 may strengthen the safety of a driver by blocking light toward the front glass (e.g., a windshield) of the vehicle among light emitted from the display apparatus 1. Although not illustrated in the drawing, an adhesive member may be between the light control layer 30 and the optical functional layer 20. The adhesive member may include at least one of an OCR, an OCA, and a PSA. The adhesive member may couple the light control layer 30 and the optical functional layer 20 to each other.

The adhesive layer 40a may be between the light control layer 30 and the cover window 40. In particular, the adhesive layer 40a may be disposed on the light control layer 30. The adhesive layer 40a may attach the cover window 40 over the display panel 10. In particular, the adhesive layer 40a may attach the cover window 40 over the display panel 10 by attaching the cover window 40 to the light control layer 30. For example, the cover window 40 may be attached over the display panel 10 by using the adhesive layer 40a. The adhesive layer 40a may include at least one of an OCR, an OCA, and a PSA. The adhesive layer 40a may be an OCR.

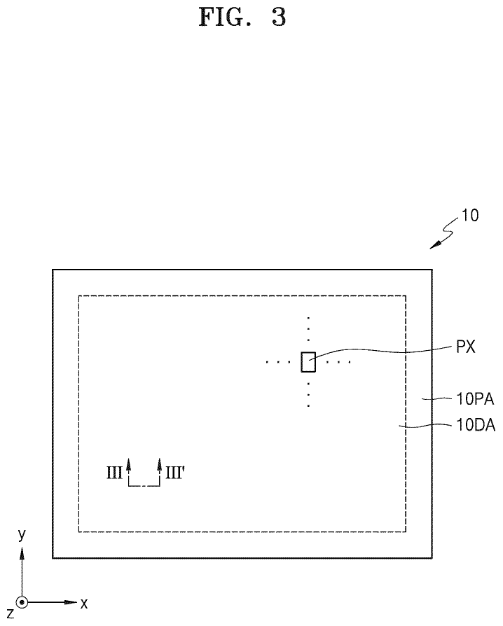

FIG. 3 is a schematic plan view of the display panel 10 of the display apparatus 1 according to an embodiment.

As shown in FIG. 3, the display panel 10 may include a panel display area 10DA and a panel peripheral area 10PA. As described above, because the display apparatus 1 includes the display panel 10, the panel display area 10DA of the display panel 10 may correspond to the display area DA of the display apparatus 1, and the panel peripheral area 10PA of the display panel 10 may correspond to the peripheral area PA of the display apparatus 1.

Accordingly, the panel display area 10DA of the display panel 10 may have a shape corresponding to the display area DA of the display apparatus 1, and the panel peripheral area 10PA of the display panel 10 may have a shape corresponding to the peripheral area PA of the display apparatus 1. In particular, the panel peripheral area 10PA of the display panel 10 may have a shape corresponding to at least a portion of the peripheral area PA of the display apparatus 1. For example, the panel display area 10DA may have a rectangular shape in which a horizontal length may be less than a vertical length, a rectangular shape in which a horizontal length may be greater than a vertical length, or a square shape. As another example, the panel display area 10DA may have various shapes, such as an oval shape or a circular shape. The panel peripheral area 10PA may surround the panel display area 10DA.

As described above, the display panel 10 may display an image, the panel display area 10DA of the display panel 10 may be an area that displays an image, and a pixel PX may be arranged in the panel display area 10DA. The pixel PX may be the smallest unit that implements an image and refers to an emission area. Multiple pixels PX may be provided, and each of the pixels PX may emit red, green, or blue light by using a display element.

The panel peripheral area 10PA may be arranged outside the panel display area 10DA. In particular, the panel peripheral area 10PA may surround the panel display area 10DA. The pixel PX may not be arranged in the panel peripheral area 10PA. For example, the panel peripheral area 10PA may be a non-display area that does not display an image. Lines and/or driving circuits for providing electrical signals to a display element corresponding to a pixel or a power line for providing power to the display element corresponding to the pixel may be arranged in the panel peripheral area 10PA.

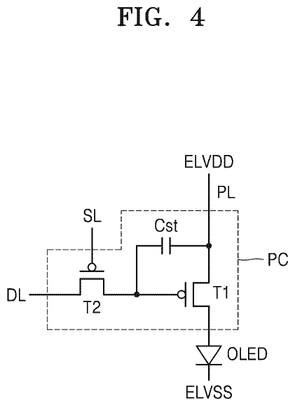

FIG. 4 is schematic diagram of an equivalent circuit of a pixel included in the display panel 10 of FIG. 3. The pixel circuit PC may be electrically connected to a display element, and a display element may correspond to a pixel. An organic light-emitting diode OLED may be shown as a display element in FIG. 4. In an embodiment, a display element may emit red, green, or blue light.

The pixel circuit PC may include a first transistor T1, a second transistor T2, and a storage capacitor Cst. The second transistor T2 may be a switching transistor, which may be electrically connected to a scan line SL and a data line DL, and may be configured to provide the first transistor T1 a data signal input from the data line DL in case of being turned on by a switching signal input from the scan line SL. The storage capacitor Cst may have an end electrically connected to the second transistor T2 and another end electrically connected to a driving voltage line PL, and may store a voltage corresponding to a difference between a voltage received from the second transistor T2 and a driving power voltage supplied to the driving voltage line PL.

The first transistor T1 may be a driving transistor, which may be electrically connected to the driving voltage line PL to receive driving voltage ELVSS and electrically connected to the storage capacitor Cst, may control a driving current flowing from the driving voltage line PL to the organic light-emitting diode OLED in accordance with a voltage value stored in the storage capacitor Cst. The organic light-emitting diode OLED may emit light having a certain brightness according to the driving current. An opposite electrode of the organic light-emitting diode OLED may receive an electrode power voltage ELVSS.

FIG. 4 illustrates that the pixel circuit PC includes two transistors and a storage capacitor, but the disclosure is not limited thereto. For example, the number of transistors or the number of storage capacitors may be variously changed according to the design of the pixel circuit PC. FIG. 4 illustrates that all of the transistors may be P-type transistors, but the disclosure is not limited thereto. For example, some of the transistors may be N-type transistors. As another example, all of the transistors may be N-type transistors.

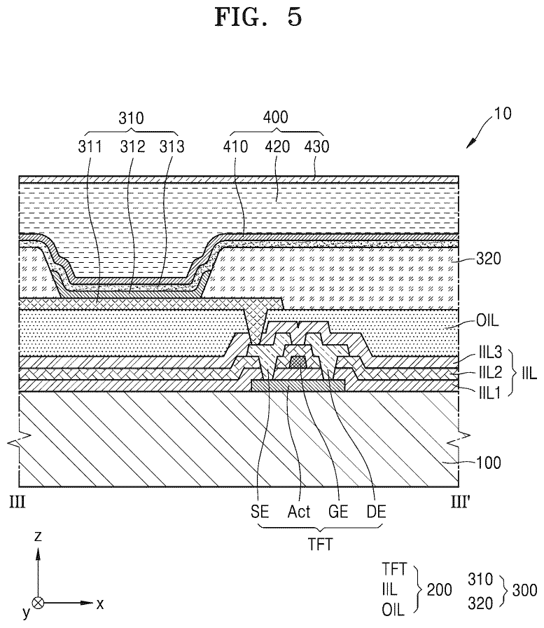

FIG. 5 is a schematic cross-sectional view of the display panel 10 of FIG. 3, taken along line III-III′. As known by those skilled in the art, the display panel 10 may further include various components in addition to the configuration shown in FIG. 5.

Referring to FIG. 5, the display panel 10 may include a substrate 100, a transistor, and a display element, wherein the transistor and the display element may be formed by various layers formed on the substrate 100. In particular, the display panel 10 may include the substrate 100, a pixel circuit layer 200, a display element layer 300, and an encapsulation layer 400.

The substrate 100 may include glass, metal, or polymer resin. The substrate 100 may be flexible or bendable. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin and a barrier layer including an inorganic material (e.g., silicon oxide (SiO_{X}), silicon nitride (SiN_{X}), silicon oxynitride (SiO_{X}N_{Y}), or the like) arranged between the two layers, and various modifications may be made.

The pixel circuit layer 200 may be disposed on the substrate 100. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, only a transistor TFT is shown in FIG. 5, and the transistor TFT may correspond to the first transistor T1 described above.

The semiconductor layer Act may be disposed on the substrate 100. The semiconductor layer Act may include polysilicon. As another example, the semiconductor layer Act may include amorphous silicon, an oxide semiconductor, an organic semiconductor, or the like. In an embodiment, the semiconductor layer Act may include a channel area, a source area, and a drain area, wherein the source area and the drain area may be respectively arranged on both sides of the channel area.

The gate insulating layer IIL1 may be disposed on the semiconductor layer Act and the substrate 100. The gate insulating layer IIL1 may include an inorganic insulating material, such as silicon oxide (SiO_{X}), silicon nitride (SiN_{X}), silicon oxynitride (SiO_{X}N_{Y}), aluminum oxide (Al₂O₃), titanium oxide (TiO₂), tantalum pentoxide (Ta₂O₅), hafnium oxide (HfO₂), zinc oxide (ZnOₓ), or the like. The zinc oxide (ZnOₓ) may include zinc oxide (ZnO) and/or zinc peroxide (ZnO₂).

The gate electrode GE may be disposed on the gate insulating layer IIL1. For example, insulation between the semiconductor layer Act and the gate electrode GE may be secured by arranging the gate insulating layer IIL1 between the semiconductor layer Act and the gate electrode GE. The gate electrode GE may overlap the channel area of the semiconductor layer Act. The gate electrode GE may include a low-resistance metal material. In an embodiment, the gate electrode GE may include a conductive material including molybdenum (Mo), aluminum (Al), copper (Cu), titanium (Ti), or the like, and may have a single-layered structure or a multi-layered structure, each including the above conductive material.

The first interlayer insulating layer IIL2 may be disposed on the gate electrode GE and the gate insulating layer IIL1. The first interlayer insulating layer IIL2 may include an inorganic insulating material, such as silicon oxide (SiO_{X}), silicon nitride (SiN_{X}), silicon oxynitride (SiO_{X}N_{Y}), aluminum oxide (Al₂O₃), titanium oxide (TiO₂), tantalum pentoxide (Ta₂O₅), hafnium oxide (HfO₂), zinc oxide (ZnOₓ), or the like.

The source electrode SE and the drain electrode DE may be disposed on the first interlayer insulating layer IIL2. Each of the source electrode SE and the drain electrode DE may be electrically connected to the semiconductor layer Act through contact holes formed in the gate insulating layer IIL1 and the first interlayer insulating layer IIL2. At least one of the source electrode SE and the drain electrode DE may include a conductive material including Mo, Al, Cu, Ti, or the like, and may have a single-layered structure or a multi-layered structure, each including the above conductive material. In an embodiment, at least one of the source electrode SE and the drain electrode DE may have a multi-layered structure of Ti/Cu/Ti.

The second interlayer insulating layer IIL3 may be disposed on the source electrode SE, the drain electrode DE, and the first interlayer insulating layer IIL2. The second interlayer insulating layer IIL3 may include an inorganic insulating material, such as silicon oxide (SiO_{X}), silicon nitride (SiN_{X}), silicon oxynitride (SiO_{X}N_{Y}), aluminum oxide (Al₂O₃), titanium oxide (TiO₂), tantalum pentoxide (Ta₂O₅), hafnium oxide (HfO₂), zinc oxide (ZnOₓ), or the like.

The organic insulating layer OIL may be disposed on the second interlayer insulating layer IIL3. The organic insulating layer OIL may serve to substantially planarize the upper portion of the pixel circuit layer 200. The organic insulating layer OIL may include, for example, an organic material, such as acryl, benzocyclobutene (BCB), hexamethyldisiloxane (HMDSO), or the like. Although FIG. 5 illustrates the organic insulating layer OIL as a single layer, various modifications may be possible, for example, the organic insulating layer OIL may also be a multi-layer.

The display element layer 300 may be disposed on the pixel circuit layer 200. The display element layer 300 may include a display element 310 and a pixel defining layer 320. The display element 310 may be electrically connected to the transistor TFT. The display element 310 may be, for example, an organic light-emitting diode including a pixel electrode 311, an opposite electrode 313, and an intermediate layer 312 arranged between the pixel electrode 311 and the opposite electrode 313 and including an emission layer. The display element 310 being electrically connected to the transistor TFT may be understood as the pixel electrode 311 of the organic light-emitting diode being electrically connected to the transistor TFT.

The pixel electrode 311 may be electrically connected to the transistor TFT by being in contact with any one of the source electrode SE and the drain electrode DE through contact holes formed in the second interlayer insulating layer IIL3 and the organic insulating layer OIL. The pixel electrode 311 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 311 may include a reflective film including silver (Ag), magnesium (Mg), Al, platinum (Pt), palladium (Pd), gold (Au), nickel (Ni), neodymium (Nd), iridium (Ir), chromium (Cr), a compound thereof, or a combination thereof. In an embodiment, the pixel electrode 311 may further include a film including ITO, IZO, ZnO, or In₂O₃ above/below the reflective film described above.

The pixel defining layer 320 may cover the edge of the pixel electrode 311. The pixel defining layer 320 may have a pixel opening portion, and the pixel opening portion may overlap the pixel electrode 311. The pixel opening portion may define an emission area of light emitted by the display element 310. The pixel defining layer 320 may include an organic insulating material and/or an inorganic insulating material. In some embodiments, the pixel defining layer 320 may include a light-blocking material.

The intermediate layer 312 may be disposed on the pixel electrode 311 and the pixel defining layer 320. The intermediate layer 312 may include a low-molecular-weight material or a polymer material. In case that the intermediate layer 312 includes a low-molecular-weight material, the intermediate layer 312 may have a structure in which a hole injection layer (HIL), a hole transport layer (HTL), an emission layer (EML), an electron transport layer (ETL), an electron injection layer (EIL), or the like may be stacked on each other in a single or complex structure, and may be formed by a vacuum deposition method. In case that the intermediate layer 312 includes a polymer material, the intermediate layer 312 may have a structure including an HTL and an EML. At this time, the HTL may include poly (3,4-ethylenedioxythiophene) (PEDOT), and the EML may include a polymer material, such as a poly (p-phenylene vinylene) (PPV)-based polymer material, a polyfluorene-based polymer material, or the like. The intermediate layer 312 may be formed by a screen printing method, an inkjet printing method, a laser induced thermal imaging (LITI) method, or the like. The intermediate layer 312 is not limited thereto and may also have various structures. Also, the intermediate layer 312 may include an integral layer over multiple pixel electrodes 311, or may include a layer patterned to correspond to each of the pixel electrodes 311.

The opposite electrode 313 may be disposed on the intermediate layer 312 and the pixel defining layer 320. The opposite electrode 313 may be formed as a single body in multiple organic light-emitting diodes to correspond to the pixel electrodes 311. The opposite electrode 313 may include a transparent conductive layer including ITO, In₂O₃, or IZO, and may also include a semi-transparent film including Al, Ag, or the like. For example, the opposite electrode 313 may include a semi-transparent film including Mg or Ag.

Because the display element 310 may be readily damaged by moisture or oxygen from the outside, the encapsulation layer 400 may cover the display element 310 to protect the display element 310. Referring to FIG. 5, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include silicon oxide (SiO_{X}), silicon nitride (SiN_{X}), and/or silicon oxynitride (SiO_{X}N_{Y}). Other layers, such as a capping layer or the like, may also be between the first inorganic encapsulation layer 410 and the opposite electrode 313 when desired. Because the first inorganic encapsulation layer 410 may be formed along an underlying structure, the upper surface of the first inorganic encapsulation layer 410 as shown in FIG. 5 may not be flat. The organic encapsulation layer 420 may cover the first inorganic encapsulation layer 410, and unlike the first inorganic encapsulation layer 410, the upper surface of the organic encapsulation layer 420 may be formed substantially flat. The organic encapsulation layer 420 may include one or more materials selected from a group consisting of polyethylene terephthalate, polyethylene naphthalate, polycarbonate, polyimide, polyethylene sulfonate, polyarylate, and HMDSO. The second inorganic encapsulation layer 430 may cover the organic encapsulation layer 420 and may include silicon oxide (SiO₂), silicon nitride (SiNₓ), silicon oxynitride (SiON), or the like.

As described above, the encapsulation layer 400 includes the first inorganic encapsulation layer 410, the organic encapsulation layer 420, and the second inorganic encapsulation layer 430. Even in case that cracks occur in the encapsulation layer 400, such cracks may not be electrically connected between the first inorganic encapsulation layer 410 and the organic encapsulation layer 420 or between the organic encapsulation layer 420 and the second inorganic encapsulation layer 430 through such as multi-layered structure of the encapsulation layer 400. Accordingly, the formation of a path, through which external moisture or oxygen, or the like penetrates the display panel 10, may be prevented or reduced.

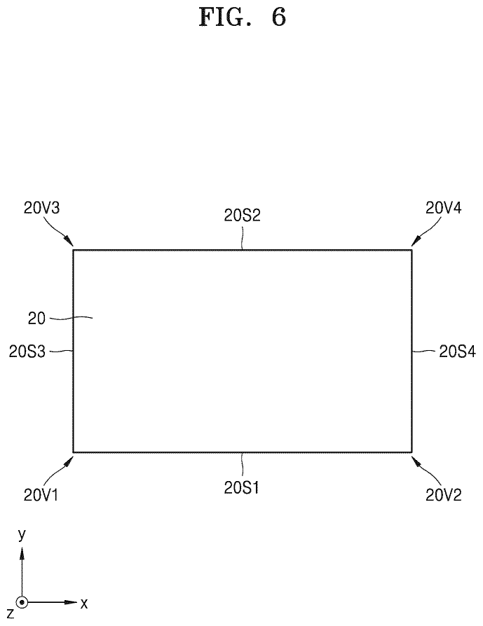

FIG. 6 is a schematic plan view of the optical functional layer 20 of the display apparatus 1 according to an embodiment.

The optical functional layer 20 may have an overall shape similar to a rectangular shape or a square shape. In particular, the optical functional layer 20 may include a first-1 side 20S1 and a first-2 side 20S2 facing each other, and a first-3 side 20S3 and a first-4 side 20S4 facing each other and positioned between the first-1 side 20S1 and the first-2 side 20S2. Herein, a side of a component means an end portion of the component in a preset direction. For example, the first-1 side 20S1 means an end portion of the optical functional layer 20 in a −y direction, and the first-2 side 20S2 means an end portion of the optical functional layer 20 in a +y direction. The first-3 side 20S3 means an end portion of the optical functional layer 20 in an −x direction, and the first-4 side 20S4 means an end portion of the optical functional layer 20 in an +x direction.

A first-1 vertex 20V1 may be formed by contacting the first-1 side 20S1 and the first-3 side 20S3 to each other, and a first-2 vertex 20V2 may be formed by contacting the first-1 side 20S1 and the first-4 side 20S4 to each other. The first-2 vertex 20V2 may be positioned to be spaced apart from the first-1 vertex 20V1 by a certain distance in the +x direction. For example, the first-1 vertex 20V1 may be a vertex positioned at the left lower portion of the optical functional layer 20, and the first-2 vertex 20V2 may be a vertex positioned at the right lower portion of the optical functional layer 20.

A first-3 vertex 20V3 may be formed by contacting the first-2 side 20S2 and the first-3 side 20S3 to each other, and a first-4 vertex 20V4 may be formed by contacting the first-2 side 20S2 and the first-4 side 20S4 to each other. The first-3 vertex 20V3 may be positioned to be spaced apart from the first-1 vertex 20V1 by a certain distance in the +y direction, and the first-4 vertex 20V4 may be positioned to be spaced apart from the first-3 vertex 20V3 by a certain distance in the +x direction. For example, the first-3 vertex 20V3 may be a vertex positioned at the left upper portion of the optical functional layer 20, and the first-4 vertex 20V4 may be a vertex positioned at the right upper portion of the optical functional layer 20.

Although FIG. 6 shows that the first-1 vertex 20V1, the first-2 vertex 20V2, the first-3 vertex 20V3, and the first-4 vertex 20V4 may be pointed or have an angular shape (or sharp corner), the disclosure is not limited thereto. For example, each of the first-1 vertex 20V1, the first-2 vertex 20V2, the first-3 vertex 20V3, and the first-4 vertex 20V4 may also have a rounded shape.

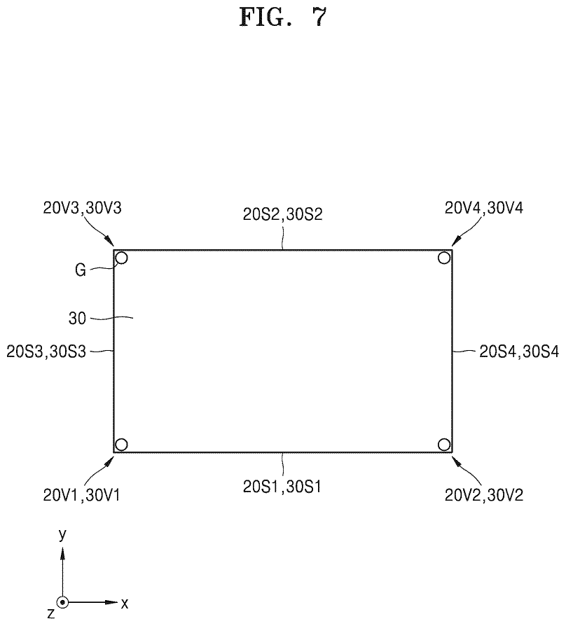

FIG. 7 is a schematic plan view of the light control layer 30 of the display apparatus 1 according to an embodiment. For convenience of explanation, In FIG. 7, the first-1 side 20S1, the first-2 side 20S2, the first-3 side 20S3, the first-4 side 20S4, the first-1 vertex 20V1, the first-2 vertex 20V2, the first-3 vertex 20V3, and the first-4 vertex 20V4 of the optical functional layer 20 may be shown together.

Similar to the optical functional layer 20, the light control layer 30 may have an overall shape similar to a rectangular shape or a square shape. In particular, the light control layer 30 may include a second-1 side 30S1 and a second-2 side 30S2 facing each other, and a second-3 side 30S3 and a second-4 side 30S4 facing each other and positioned between the second-1 side 30S1 and the second-2 side 30S2.

A second-1 vertex 30V1 may be formed by contacting the second-1 side 30S1 and the second-3 side 30S3 to each other, and a second-2 vertex 30V2 may be formed by contacting the second-1 side 30S1 and the second-4 side 30S4 to each other. The second-2 vertex 30V2 may be positioned to be spaced apart from the second-1 vertex 30V1 by a certain distance in the +x direction. For example, the second-1 vertex 30V1 may be a vertex positioned at the left lower portion of the light control layer 30, and the second-2 vertex 30V2 may be a vertex positioned at the right lower portion of the light control layer 30.

A second-3 vertex 30V3 may be formed by contacting the second-2 side 30S2 and the second-3 side 30S3 to each other, and a second-4 vertex 30V4 may be formed by contacting the second-2 side 30S2 and the second-4 side 30S4 to each other. The second-3 vertex 30V3 may be positioned to be spaced apart from the second-1 vertex 30V1 by a certain distance in the +y direction, and the second-4 vertex 30V4 may be positioned to be spaced apart from the second-3 vertex 30V3 by a certain distance in the +x direction. For example, the second-3 vertex 30V3 may be a vertex positioned at the left upper portion of the light control layer 30, and the second-4 vertex 30V4 may be a vertex positioned at the right upper portion of the light control layer 30.

Although FIG. 7 shows that the second-1 vertex 30V1, the second-2 vertex 30V2, the second-3 vertex 30V3, and the second-4 vertex 30V4 may be pointed or have an angular shape, the disclosure is not limited thereto. For example, each of the second-1 vertex 30V1, the second-2 vertex 30V2, the second-3 vertex 30V3, and the second-4 vertex 30V4 may also have a rounded shape.

The light control layer 30 may include a groove G adjacent to the vertex thereof. Multiple grooves G may be provided. For example, the light control layer 30 may include multiple grooves G. The grooves G may be respectively arranged adjacent to the vertexes of the light control layer 30 in a plan view. For example, the light control layer 30 may include a groove G arranged adjacent to the second-1 vertex 30V1 in a plan view and a groove G arranged adjacent to the second-2 vertex 30V2 in a plan view. The light control layer 30 may include a groove G arranged adjacent to the second-3 vertex 30V3 in a plan view and a groove G arranged adjacent to the second-4 vertex 30V4 in a plan view.

The area of the light control layer 30 may be equal to or similar to the area of the optical functional layer 20, and the shape of the light control layer 30 may be the same as or similar to the shape of the optical functional layer 20. For example, in a plan view, the light control layer 30 and the optical functional layer 20 may completely overlap each other. Accordingly, the sides of the light control layer 30 may respectively overlap the sides of the optical functional layer 20 in a plan view, and the vertexes of the light control layer 30 may respectively overlap the vertexes of the optical functional layer 20 in a plan view.

In particular, as shown in FIG. 7, the second-1 side 30S1 may overlap the first-1 side 20S1 in a plan view, and the second-2 side 30S2 may overlap the first-2 side 20S2 in a plan view. The second-3 side 30S3 may overlap the first-3 side 20S3 in a plan view, and the second-4 side 30S4 may overlap the first-4 side 20S4 in a plan view. The second-1 vertex 30V1 may overlap the first-1 vertex 20V1 in a plan view, and the second-2 vertex 30V2 may overlap the first-2 vertex 20V2 in a plan view. The second-3 vertex 30V3 may overlap the first-3 vertex 20V3 in a plan view, and the second-4 vertex 30V4 may overlap the first-4 vertex 20V4 in a plan view.

In other words, the sides of the light control layer 30 may respectively coincide with the sides of the optical functional layer 20 in a plan view, and the vertexes of the light control layer 30 may respectively coincide with the vertexes of the optical functional layer 20 in a plan view. In particular, as shown in FIG. 7, the second-1 side 30S1 may coincide with the first-1 side 20S1 in a plan view, and the second-2 side 30S2 may coincide with the first-2 side 20S2 in a plan view. The second-3 side 30S3 may coincide with the first-3 side 20S3 in a plan view, and the second-4 side 30S4 may coincide with the first-4 side 20S4 in a plan view. The second-1 vertex 30V1 may coincide with the first-1 vertex 20V1 in a plan view, and the second-2 vertex 30V2 may coincide with the first-2 vertex 20V2 in a plan view. The second-3 vertex 30V3 may coincide with the first-3 vertex 20V3 in a plan view, and the second-4 vertex 30V4 may coincide with the first-4 vertex 20V4 in a plan view.

As described above, the second-1 vertex 30V1, the second-2 vertex 30V2, the second-3 vertex 30V3, and the second-4 vertex 30V4 may respectively overlap the first-1 vertex 20V1, the first-2 vertex 20V2, the first-3 vertex 20V3, and the first-4 vertex 20V4. Accordingly, the groove G arranged adjacent to the second-1 vertex 30V1 in a plan view may be arranged adjacent to the first-1 vertex 20V1 in a plan view. Similarly, the groove G arranged adjacent to the second-2 vertex 30V2 in a plan view may be arranged adjacent to the first-2 vertex 20V2 in a plan view. The groove G arranged adjacent to the second-3 vertex 30V3 in a plan view may be arranged adjacent to the first-3 vertex 20V3 in a plan view. The groove G arranged adjacent to the second-4 vertex 30V4 in a plan view may be arranged adjacent to the first-4 vertex 20V4 in a plan view.

The grooves G may be used as alignment marks in a process of manufacturing the display apparatus 1 as to be described below. Although FIG. 7 shows that each of the grooves G has a circular shape in a plan view, the disclosure is not limited thereto.

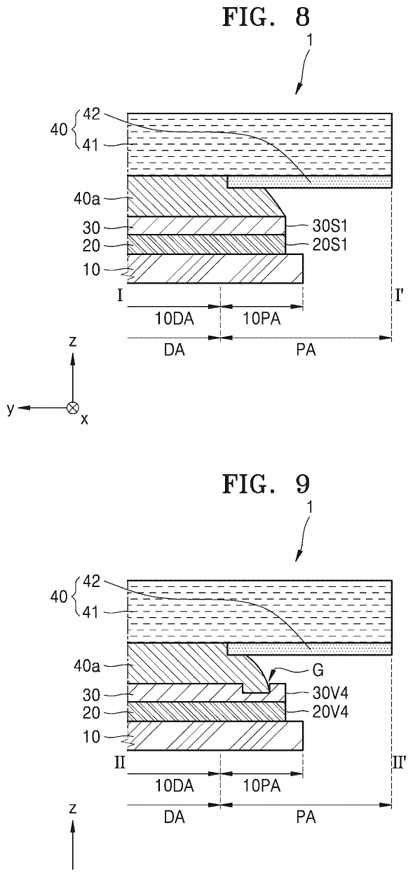

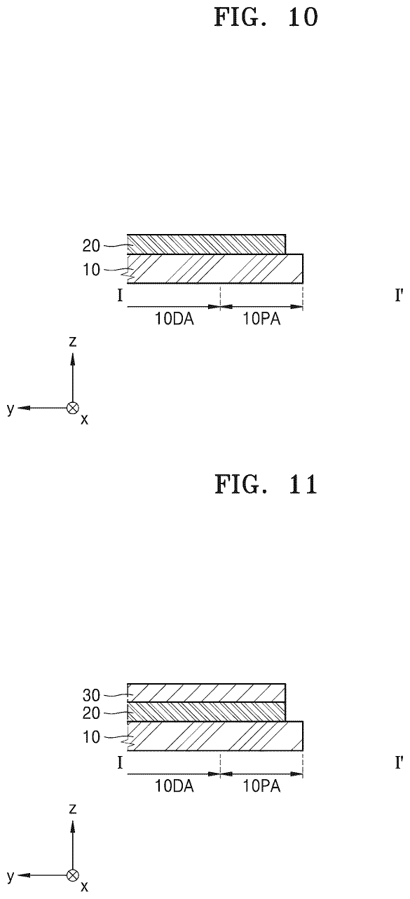

FIG. 8 is a schematic cross-sectional view of the display apparatus 1 of FIG. 1, taken along line I-I′. FIG. 9 is a schematic cross-sectional view of the display apparatus 1 of FIG. 1, taken along line II-II′.

As described above, the light control layer 30 and the optical functional layer 20 completely overlap each other in a plan view, and thus a side of the light control layer 30 may be aligned with a side of the optical functional layer 20. A vertex of the light control layer 30 may be aligned with a vertex of the optical functional layer 20.

For example, as shown in FIG. 8, the second-1 side 30S1 of the light control layer 30 may be aligned with the first-1 side 20S1 of the optical functional layer 20. Although not illustrated in the drawing, the above description about the positional relationship between the second-1 side 30S1 and the first-1 side 20S1 may also be applied to the positional relationship between the second-2 side 30S2 and the first-2 side 20S2, the positional relationship between the second-3 side 30S3 and the first-3 side 20S3, and the positional relationship between the second-4 side 30S4 and the first-4 side 20S4. Accordingly, redundant descriptions overlapping the above description are omitted.

Similarly, as shown in FIG. 9, the second-4 vertex 30V4 of the light control layer 30 may be aligned with the first-4 vertex 20V4 of the optical functional layer 20. Although not illustrated in the drawing, the above description about the positional relationship between the second-4 vertex 30V4 and the first-4 vertex 20V4 may also be applied to the positional relationship between the second-1 vertex 30V1 and the first-1 vertex 20V1, the positional relationship between the second-2 vertex 30V2 and the first-2 vertex 20V2, and the positional relationship between the second-3 vertex 30V3 and the first-3 vertex 20V3. Accordingly, redundant descriptions overlapping the above description are omitted.

The cover window 40 may include a cover window substrate 41 and a light-blocking layer 42. The cover window substrate 41 may form the overall exterior of the cover window 40. For example, the cover window substrate 41 may have substantially the same shape as the cover window 40. The cover window substrate 41 may include glass, sapphire, or plastic. For example, the cover window substrate 41 may be an ultra-thin glass (UTG®) or colorless polyimide (CPI) of which the strength may be strengthened by a method such as chemical strengthening, thermal strengthening, or the like. The cover window substrate 41 may have a structure in which a flexible polymer layer may be disposed on a surface of a glass substrate, or may only include a polymer layer.

The light-blocking layer 42 may be disposed below the cover window substrate 41. In particular, the light-blocking layer 42 may be disposed below a portion of the cover window substrate 41, which corresponds to the peripheral area PA of the display apparatus 1. Accordingly, the light-blocking layer 42 may be disposed in the panel peripheral area 10PA of the display panel 10. The light-blocking layer 42 may extend along the periphery of the cover window substrate 41, and the light-blocking layer 42 may have a shape corresponding to the peripheral area PA of the display apparatus 1.

In an embodiment, the light-blocking layer 42 may include a light-blocking material. For example, the light-blocking layer 42 may include an opaque material that blocks light so that wires or circuits of the display panel 10 may not be identified from the outside. The light-blocking material may include at least one of a black dye and black particles. For example, the light-blocking material may include Cr, CrO_{X}, Cr/CrO_{X}, Cr/CrO_{X}/CrN_{Y}, a resin (a carbon pigment, a red-green-blue (RGB) mixed pigment), graphite, a non-Cr based pigment, a lactam-based pigment, or a perylene-based pigment. The light-blocking material may include a black organic pigment, and the black organic pigment may include one or more selected from a group consisting of aniline black, lactam black, and perylene black.

The grooves G may be arranged in the peripheral area PA of the display apparatus 1. For example, the groove G may be arranged in the panel peripheral area 10PA of the display panel 10. The adhesive layer 40a may fill the groove G.

The description of the display apparatus 1 may be made above, but the disclosure is not limited thereto. A method of manufacturing the display apparatus 1 may also be included in the scope of the disclosure. Hereinafter, the method of manufacturing the display apparatus 1 is described.

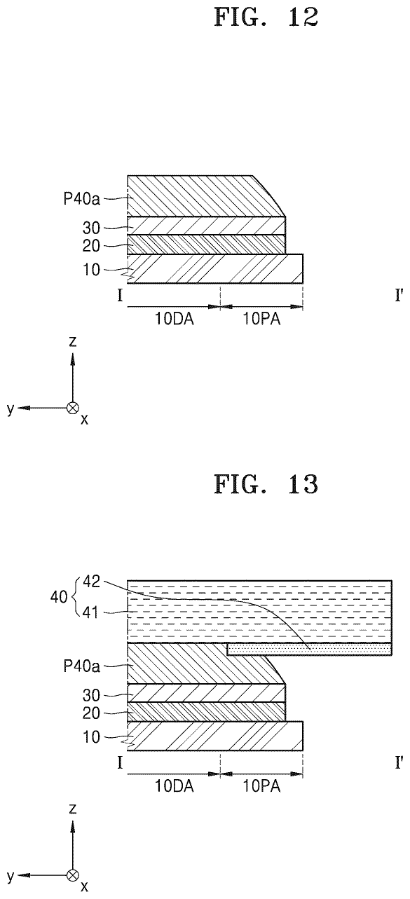

FIGS. 10 to 14 are schematic diagrams for describing a process of manufacturing the display apparatus 1 according to an embodiment. For convenience of explanation, in FIGS. 10 to 14, the process of manufacturing the display apparatus 1 may be described based on the cross section of the display apparatus 1 of FIG. 1 taken along the line I-I′.

First, as shown in FIG. 10, the optical functional layer 20 may be attached to the display panel 10. In particular, the optical functional layer 20 may be attached to the upper surface of the display panel 10 (in a +z direction). Although not illustrated in the drawing, an adhesive member may be between the optical functional layer 20 and the display panel 10. The adhesive member may include at least one of an OCR, an OCA, and a PSA. The adhesive member may couple the optical functional layer 20 and the display panel 10 to each other. For example, the optical functional layer 20 may be attached to the display panel 10 by using the adhesive member.

Then, as shown in FIG. 11, the light control layer 30 may be attached to the optical functional layer 20. The area of the light control layer 30 may be the same as or similar to the area of the optical functional layer 20, and the shape of the light control layer 30 may be the same as or similar to the shape of the optical functional layer 20. In a plan view, the light control layer 30 may be attached to the optical functional layer 20 so that the light control layer 30 and the optical functional layer 20 completely overlap each other. To this end, the grooves G described above with reference to FIG. 7 may be used. The grooves G may be respectively arranged adjacent to the vertexes of the light control layer 30 in a plan view. The light control layer 30 may be attached to the optical functional layer 20 by aligning the light control layer 30 and the optical functional layer 20 with each other by using the grooves G so that the sides of the light control layer 30 respectively overlap the sides of the optical functional layer 20, and the vertexes of the light control layer 30 respectively overlap the vertexes of the optical functional layer 20.

In other words, the light control layer 30 may be attached to the optical functional layer 20 in case of aligning the light control layer 30 and the optical functional layer 20 with each other by using the grooves G so that the sides of the light control layer 30 respectively coincide with the sides of the optical functional layer 20, and the vertexes of the light control layer 30 respectively coincide with the vertexes of the optical functional layer 20. For example, the grooves G of the light control layer 30 may be used as alignment marks.

Generally, in case that a light control layer is attached to an optical functional layer by using an adhesive member, the sides and the vertexes of the light control layer may be used to attach the light control layer to a preset position on the optical functional layer. In a process of attaching the light control layer to the optical functional layer, the sides and the vertexes of the light control layer should be clearly recognized on the optical functional layer. To this end, the area of the light control layer should be less than the area of the optical functional layer. For example, the sides and the vertexes of the light control layer may be clearly recognized on the optical functional layer by positioning the sides and the vertexes of the light control layer on the optical functional layer.

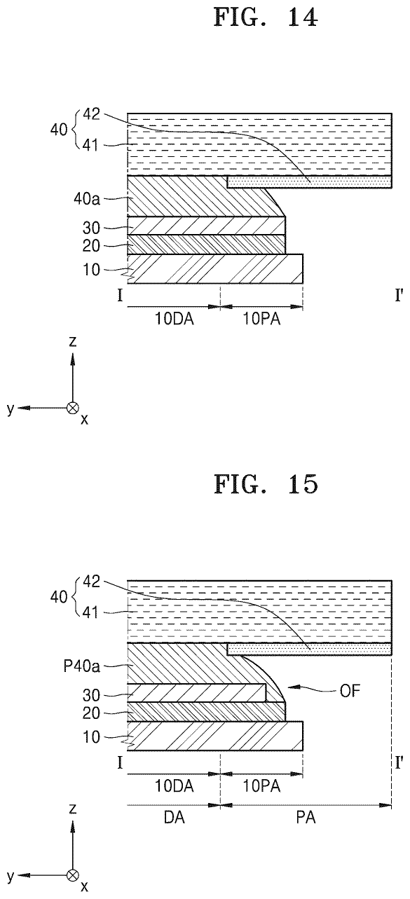

For example, as shown in FIG. 15, which may be a schematic cross-sectional view of a portion of a display apparatus being manufactured according to a comparative example, a side of the light control layer 30 may be positioned on the optical functional layer 20. For example, the area of the light control layer 30 of the display apparatus being manufactured according to the comparative example may be less than the area of the optical functional layer 20, and accordingly, the sides and the vertexes of the light control layer 30 may be positioned on the optical functional layer 20.

However, the light control layer 30 of the embodiment includes the grooves G, and the grooves G may be used as alignment marks. Accordingly, the area of the light control layer 30 may not be less than the area of the optical functional layer 20, and the light control layer 30 may have an area that may be the same as or similar to the area of the optical functional layer 20. The light control layer 30 may have a shape that may be the same as or similar to the shape of the optical functional layer 20. Because an area in which an adhesive layer formation material applied on the light control layer 30 spreads increases, the adhesive layer formation material applied to the light control layer 30 may be more uniformly applied to the light control layer 30.

Then, as shown in FIG. 12, a preliminary adhesive layer P40a may be formed on the light control layer 30. In particular, as the adhesive layer formation material may be applied to the light control layer 30 and ultraviolet rays may be irradiated to the adhesive layer formation material, the adhesive layer formation material may be pre-cured. Accordingly, the preliminary adhesive layer P40a may be formed on the light control layer 30. Here, the “preliminary adhesive layer” may mean a layer that may be pre-cured by applying an adhesive layer formation material and irradiating ultraviolet rays to the adhesive layer formation material. The adhesive layer formation material may be applied to a preset position by using the grooves G. For example, the grooves G of the light control layer 30 may be used as alignment marks.

The adhesive layer formation material may include at least one formation material from among an OCR, an OCA, and a PSA. For example, at least one of the OCR, the OCA, and the PSA may be formed by pre-curing the adhesive layer formation material and curing (for example, main-curing) the pre-cured adhesive layer formation material. The formation of the preliminary adhesive layer P40a by applying the adhesive layer formation material and pre-curing the adhesive layer formation material by irradiating ultraviolet rays may be a technique used in the manufacturing of a display apparatus, and thus the detailed description thereof is omitted.

Although not illustrated in FIG. 12, the adhesive layer formation material may fill the grooves G in case of applying the adhesive layer formation material to the light control layer 30. The adhesive layer formation material filling the grooves G may also be irradiated with ultraviolet rays, and accordingly, the adhesive layer formation material filling the grooves G may also be pre-cured. For example, a portion of the preliminary adhesive layer P40a may fill the grooves G.

Then, as shown in FIG. 13, the cover window 40 may be disposed on the preliminary adhesive layer P40a, and the cover window 40 may be pressurized. The cover window 40 may be pressurized by the weight of the cover window 40 or may be pressurized by applying an external force. The pressurizing of the cover window 40 may be a technique used in the manufacturing of a display apparatus, and thus the detailed description thereof is omitted.

In general, in case that the sides and the vertexes of a light control layer are positioned on an optical functional layer by reducing the area of the light control layer to be less than the area of the optical control layer, a preliminary adhesive layer may overflow. In particular, in case that a cover window is pressurized after arranging the cover window on the preliminary adhesive layer on the light control layer, the preliminary adhesive layer may overflow. Accordingly, a portion of the preliminary layer may be disposed on a layer disposed below the light control layer.

As shown in FIG. 15 which is a schematic cross-sectional view of a portion of the display apparatus being manufactured according to the comparative example, in the display apparatus being manufactured according to the comparative example, the area of the light control layer 30 may be less than the area of the optical functional layer 20, and thus an organic material layer OF may be disposed on the optical functional layer 20. For example, the organic material layer OF may be a portion of the preliminary adhesive layer P40a that overflows in a process of arranging the cover window 40 on the preliminary adhesive layer P40a and pressurizing the cover window 40.

Because the organic material layer OF has fluidity before being main-cured, a portion of the organic material layer OF may penetrate between the optical functional layer 20 and the light control layer 30. A portion of the organic material layer OF may reach an area corresponding to the display area DA, and such a portion of the organic material layer OF may generate a stain on the display apparatus, thereby decreasing the display quality of the display apparatus. For example, a defect may occur in the manufacturing process of the display apparatus.

However, the light control layer 30 of the embodiment may have an area that may be the same as or similar to the area of the optical functional layer 20, and the sides and the vertexes of the light control layer 30 may not be positioned on the optical functional layer 20. For example, the sides of the light control layer 30 respectively coincide with the sides of the optical functional layer 20, and the vertexes of the light control layer 30 respectively coincide with the vertexes of the optical functional layer 20. Accordingly, in a process of manufacturing the display apparatus 1 according to an embodiment, even in case that a portion of the preliminary adhesive layer P40a overflows, the overflowed portion of the preliminary adhesive layer P40a may be disposed on the display panel 10. The overflowed portion of the preliminary adhesive layer P40a may be positioned farther away from an area corresponding to the display area DA as compared with the organic material layer OF shown in FIG. 15. Accordingly, even in case that the overflowed portion of the preliminary adhesive layer P40a penetrates between the display panel 10 and the optical functional layer 20, it may be difficult for the overflowed portion of the preliminary adhesive layer P40a to reach the area corresponding to the display area DA. Accordingly, the overflowed portion of the preliminary adhesive layer P40a may not generate a stain on the display apparatus 1 or the degree of stain may be reduced. For example, the possibility of defect occurrence may be reduced in the manufacturing process of the display apparatus.

Then, as shown in FIG. 14, the adhesive layer 40a may be formed by irradiating ultraviolet rays to the preliminary adhesive layer P40a. Here, the “adhesive layer” may mean a layer that may be main-cured by irradiating ultraviolet rays to the preliminary adhesive layer P40a. The adhesive layer 40a may include at least one of an OCR, an OCA, and a PSA. The formation of the adhesive layer 40a by main-curing the preliminary adhesive layer P40a by irradiating ultraviolet rays to the preliminary adhesive layer P40a may be a technique used in the manufacturing of a display apparatus, and thus a detailed description thereof is omitted.

Because a portion of the preliminary adhesive layer P40a which fills the grooves G, may also be irradiated with ultraviolet rays, a portion of the adhesive layer 40a may fill the grooves G as shown in FIG. 9.

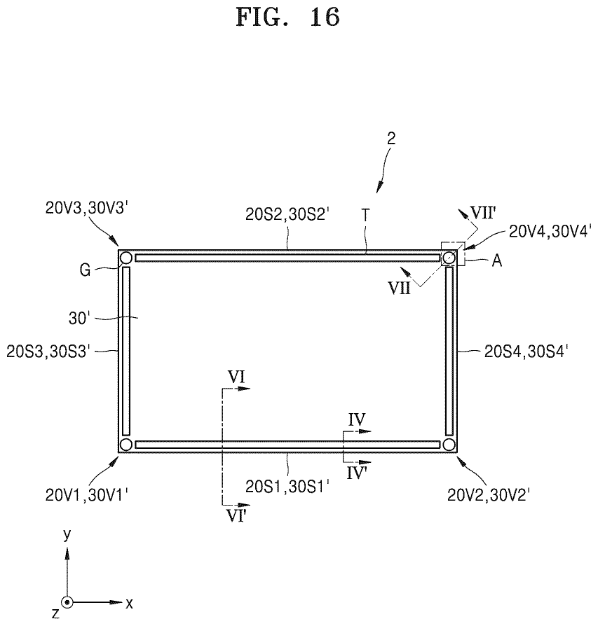

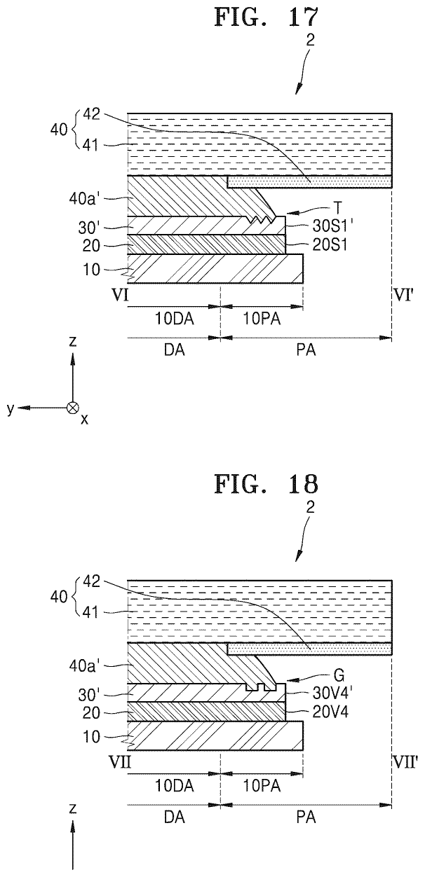

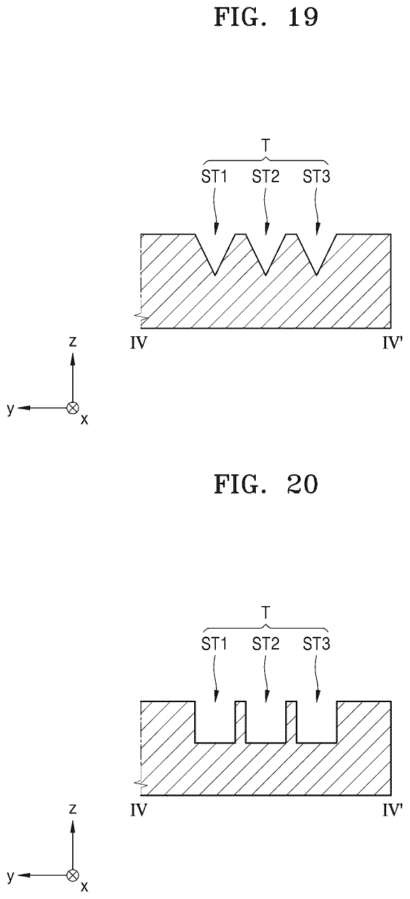

FIG. 16 is a schematic plan view of the light control layer 30 of a display apparatus 2 according to an embodiment. FIG. 17 is a schematic cross-sectional view of a portion of the display apparatus 2 according to an embodiment. FIG. 18 is a schematic cross-sectional view of a portion of the display apparatus 2 according to an embodiment. FIG. 17 is a schematic cross-sectional view of a cross section of the display apparatus 2 taken along the line VI-VI′ of FIG. 16 corresponding to the line I-I′ of FIG. 1. FIG. 18 is a schematic cross-sectional view of a cross section of the display apparatus 2 taken along line VII-VII′ of FIG. 16 corresponding to the line II-II′ of FIG. 1. For example, FIG. 17 corresponds to FIG. 8, and FIG. 18 corresponds to FIG. 9. Because the display apparatus 2 according to an embodiment may be similar to the display apparatus 1 described above with reference to FIGS. 1 to 9, differences from the display apparatus 1 described above with reference to FIGS. 1 to 9 are hereinafter described. In FIGS. 16 to 18, the same reference numerals as those in FIGS. 1 to 9 refer to the same members, and redundant descriptions thereof are omitted.

The display apparatus 1 according to the embodiment described above with reference to FIGS. 1 to 9 may include the display panel 10, the optical functional layer 20, the light control layer 30, the cover window 40, and the adhesive layer 40a. The light control layer 30 of the display apparatus 1 according to the embodiment described above with reference to FIGS. 1 to 9 may include the grooves G. The display apparatus 2 according to the embodiment may include the display panel 10, the optical functional layer 20, a light control layer 30′, the cover window 40, and an adhesive layer 40a′, and the light control layer 30′ of the display apparatus 2 according to the embodiment may also include the grooves G.

However, as shown in FIG. 16, the light control layer 30′ of the display apparatus 2 according to the embodiment may further include a trench T. Multiple trenches T may be provided. For example, the light control layer 30′ of the display apparatus 2 may further include multiple trenches T. The trenches T may be respectively arranged between the grooves G in a plan view. In particular, a trench T may be arranged between the groove G adjacent to the second-1 vertex 30V1′ and the groove G adjacent to the second-2 vertex 30V2′, and a trench T may be arranged between the groove G adjacent to the second-3 vertex 30V3′ and the groove G adjacent to the second-4 vertex 30V4′. A trench T may be arranged between the groove G adjacent to the second-1 vertex 30V1′ and the groove G adjacent to the second-3 vertex 30C3′, and a trench T may be arranged between the groove G adjacent to the second-2 vertex 30V2′ and the groove G adjacent to the second-4 vertex 30V4′.

The trench T may extend along a side of the light control layer 30′. For example, each of the trenches T may extend along a side of the light control layer 30′. In particular, the trench T between the groove G adjacent to the second-1 vertex 30V1′ and the groove G adjacent to the second-2 vertex 30V2′ may extend along the second-1 side 30S1′. For example, the trench T between the groove G adjacent to the second-1 vertex 30V1′ and the groove G adjacent to the second-2 vertex 30V2′ may extend in a first direction (e.g., an x-axis direction). Similarly, the trench T between the groove G adjacent to the second-3 vertex 30V3′ and the groove G adjacent to the second-4 vertex 30V4′ may extend along the second-2 side 30S2′. For example, the trench T between the groove G adjacent to the second-3 vertex 30V3′ and the groove G adjacent to the second-4 vertex 30V4′ may extend in the first direction (e.g., the x-axis direction).

The trench T between the groove G adjacent to the second-1 vertex 30V1′ and the groove G adjacent to the second-3 vertex 30V3′ may extend along the second-3 side 30S3′. For example, the trench T between the groove G adjacent to the second-1 vertex 30V1′ and the groove G adjacent to the second-3 vertex 30V3′ may extend in a second direction (e.g., a y-axis direction) intersecting the first direction (e.g., the x-axis direction). The trench T between the groove G adjacent to the second-2 vertex 30V2′ and the groove G adjacent to the second-4 vertex 30V4′ may extend along the second-4 side 30S4′. For example, the trench T between the groove G adjacent to the second-2 vertex 30V2′ and the groove G adjacent to the second-4 vertex 30V4′ may extend in the second direction (e.g., the y-axis direction).

In other words, the trenches T may respectively be arranged adjacent to the sides of the light control layer 30. A trench T may be arranged adjacent to the second-1 side 30S1′, and a trench T may be arranged adjacent to the second-2 side 30S2′. A trench T may be arranged adjacent to the second-3 side 30S3′, and a trench T may be arranged adjacent to the second-4 side 30S4′. As described below, the trenches T may prevent or reduce the overflow of the adhesive layer formation material during the process of manufacturing the display apparatus 2 by increasing the surface area of the light control layer 30.

As shown in FIG. 17, the trenches T may be arranged in the peripheral area PA of the display apparatus 2. For example, the trench T may be arranged in the panel peripheral area 10PA of the display panel 10. The adhesive layer 40a′ may fill the trench T. As shown in FIG. 18, the grooves G may also be arranged in the peripheral area PA of the display apparatus 2. For example, the groove G may be arranged in the panel peripheral area 10PA of the display panel 10. The adhesive layer 40a′ may fill the groove G.

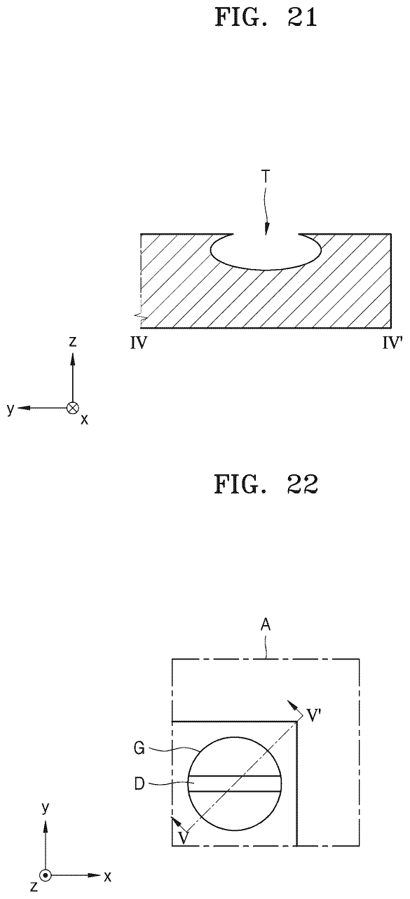

FIGS. 19 to 21 are schematic diagrams for describing the schematic cross-sectional shapes of the trench T of FIG. 16. For convenience of explanation, in FIGS. 19 to 21, the cross-sectional shapes of the trench T may be described based on the cross section of the light control layer 30′ of FIG. 16 taken along line IV-IV′.

As shown in FIG. 19, the trench T may include multiple sub-trenches. For example, the trench T may include a first sub-trench ST1, a second sub-trench ST2, and a third sub-trench ST3. The cross-sectional shape of each of the first sub-trench ST1, the second sub-trench ST2, and the third sub-trench ST3 may have an inverted triangular shape. As another example, as shown in FIG. 20, the cross-sectional shape of each of the first sub-trench ST1, the second sub-trench ST2, and the third sub-trench ST3 may have a square shape. As another example, as shown in FIG. 21, the trench T may include a trench, and the cross-sectional shape of the trench T may be similar to an oval shape. However, the disclosure is not limited thereto.

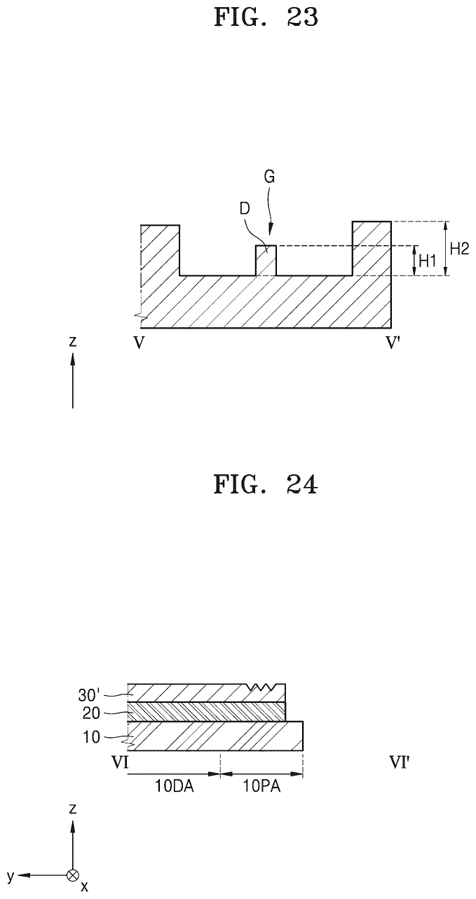

FIG. 22 is a schematic enlarged plan view of a portion A of the light control layer 30′ of FIG. 16.

As shown in FIG. 22, the display apparatus 2 may further include a control dam D. The control dam D may be arranged in the groove G of the light control layer 30′. In particular, the control dam D may be arranged in each of the grooves G of the light control layer 30′. The control dam D may extend in a direction. FIG. 22 shows that the control dam D extends in the first direction (e.g., the x-axis direction), but the disclosure is not limited thereto. For example, the control dam D may extend in the second direction (e.g., the y-axis direction). Alternatively, the control dam D may also extend in a direction between the first direction (e.g., the x-axis direction) and the second direction (e.g., the y-axis direction). Accordingly, the control dam D may be in contact with the side surface of the groove G. The control dam D according to an embodiment may be integrally provided with the light control layer 30′. For example, the groove G may be formed by removing a portion of a preliminary light control layer, and the control dam D may be formed by not removing a preset portion in case of removing a portion of the preliminary light control layer.

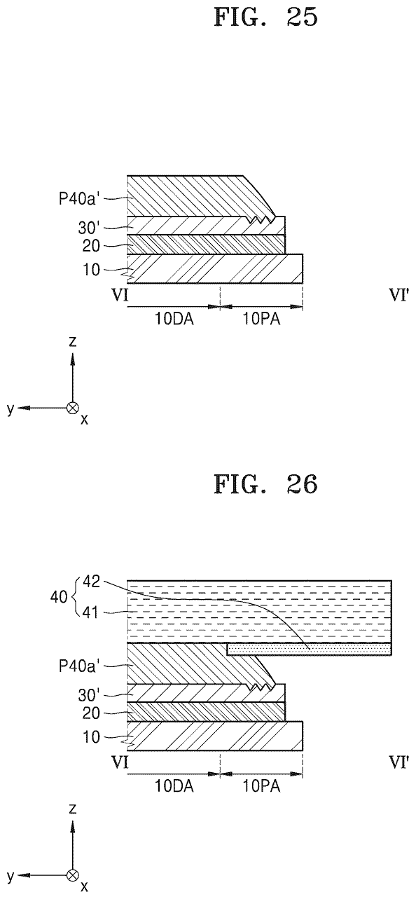

FIG. 23 is a schematic diagram for describing the cross-sectional shapes of the groove G and the control dam D of FIG. 22. In particular, FIG. 23 is a schematic cross-sectional view of the light control layer 30′ of FIG. 22 taken along line V-V′.

As shown in FIG. 23, the control dam D may be arranged in the groove G of the light control layer 30′. The height of the control dam D based on the bottom surface of the groove G (in a −z direction) may be a first height H1, and the height of the light control layer 30′ based on the bottom surface of the groove G (in the −z direction) may be a second height H2. Here, the height of the control dam D based on the bottom surface of the groove G (in the −z direction) means the shortest distance between the bottom surface of the groove G (in the −z direction) and the upper surface of the control dam D (in a +z direction) in a thickness direction (e.g., a z-axis direction). Here, the height H2 of the light control layer 30′ based on the bottom surface of the groove G (in the −z direction) means the shortest distance between the bottom surface of the groove G (in the −z direction) and the upper surface of the light control layer 30′ (in the +z direction) in the thickness direction (e.g., the z-axis direction).

The first height H1 may be less than the second height H2. For example, the second height H2 may be greater than the first height H1. As described above, because the groove G of the light control layer 30′ may be used as an alignment mark, and the height of the light control layer 30′ including the groove G may be high, the groove G may be better recognized by workers and/or equipment in the process of manufacturing the display apparatus 1.

The description of the display apparatus 2 may be made above, but the disclosure is not limited thereto. A method of manufacturing the display apparatus 2 may also be included in the range of the disclosure. Hereinafter, the method of manufacturing the display apparatus 2 is described.

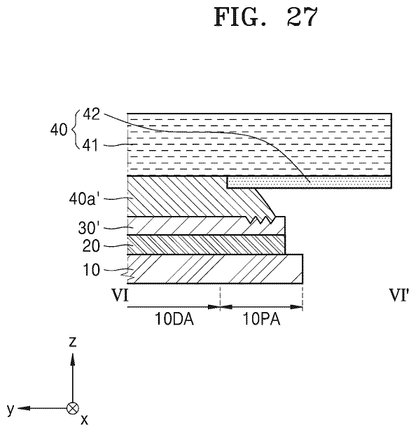

FIGS. 24 to 27 are schematic diagrams for describing a process of manufacturing the display apparatus 2 according to an embodiment. For convenience of explanation, in FIGS. 24 to 27, the process of manufacturing the display apparatus 2 may be described based on the cross section of the display apparatus 2 of FIG. 17 taken along the line VI-VI′. Because the process of manufacturing the display apparatus 2 according to the embodiment may be similar to the process of manufacturing the display apparatus I described above with reference to FIGS. 10 to 14, hereinafter, differences from the process of manufacturing the display apparatus 1 described above with reference to FIGS. 10 to 14 may be described. In FIGS. 24 to 27, the same reference numerals as those in FIGS. 10 to 14 refer to the same members, and redundant descriptions thereof are omitted.

First, similar to the process of manufacturing the display apparatus 1 described above with reference to FIG. 10, the optical functional layer 20 may be attached to the display panel 10. As shown in FIG. 24, the light control layer 30′ may be attached to the optical functional layer 20. The area of the light control layer 30′ may be the same as or similar to the area of the optical functional layer 20, and the shape of the light control layer 30′ may be the same as or similar to the shape of the optical functional layer 20. The light control layer 30′ may be attached to the optical functional layer 20 by aligning the light control layer 30′ and the optical functional layer 20 with each other by using the grooves G so that the sides of the light control layer 30′ respectively overlap the sides of the optical functional layer 20, and the vertexes of the light control layer 30′ respectively overlap the vertexes of the optical functional layer 20.

As described above with reference to FIG. 16, the light control layer 30′ may include the trenches T, and the trenches T may respectively be arranged adjacent to the sides of the light control layer 30′ in a plan view. Although not illustrated in FIG. 24, as described above with reference to FIG. 22, the control dam D may be arranged in each of the grooves G. The control dam D may be integrally provided with the light control layer 30′.

Then, as shown in FIG. 25, the preliminary adhesive layer P40a′ may be formed on the light control layer 30′. In particular, as the adhesive layer formation material may be applied to the light control layer 30′ and ultraviolet rays may be irradiated to the adhesive layer formation material, the adhesive layer formation material may be pre-cured.

In case that the adhesive layer formation material is applied to the light control layer 30′, the adhesive layer formation material may fill the trenches T. For example, the adhesive layer formation material may also fill the trenches T. The adhesive layer formation material filling the trenches T may be irradiated with ultraviolet rays, and accordingly, the adhesive layer formation material filling the trenches T may also be pre-cured. For example, a portion of the preliminary adhesive layer P40a′ may fill the trenches T.

Although not illustrated in FIG. 25, the adhesive layer formation material may fill the grooves G in case of applying the adhesive layer formation material to the light control layer 30′. For example, the adhesive layer formation material may also fill the grooves G. The adhesive layer formation material filling the grooves G may also be irradiated with ultraviolet rays, and accordingly the adhesive layer formation material filling the grooves G may also be pre-cured. For example, a portion of the preliminary adhesive layer P40a′ may fill the grooves G.

Then, as shown in FIG. 26, the cover window 40 may be disposed on the preliminary adhesive layer P40a′, and the cover window 40 may be pressurized. Because the light control layer 30′ includes the trenches T, the surface area of the light control layer 30′ may increase. For example, a contact surface between a layer disposed below the preliminary adhesive layer P40a′ and the preliminary adhesive layer P40a′ may increase. Because the control dam D may be arranged in the groove G of the light control layer 30′, a contact surface between the layer disposed below the preliminary adhesive layer P40a′ and the preliminary adhesive layer P40a′ may increase. Accordingly, even in case that the cover window 40 on the preliminary adhesive layer P40a′ is pressurized, a portion of the preliminary adhesive layer P40a′ may not overflow, or even in case that the portion of the preliminary adhesive layer P40a′ does overflow, the degree of overflow may be reduced. For example, the possibility of defect occurrence may be reduced in the manufacturing process of the display apparatus.

Then, as shown in FIG. 27, the adhesive layer 40a′ may be formed by irradiating ultraviolet rays to the preliminary adhesive layer P40a′. Because a portion of the preliminary adhesive layer P40a′ which fills the trenches T may be also irradiated with ultraviolet rays, a portion of the adhesive layer 40a′ may fill the trenches T. Because a portion of the preliminary adhesive layer P40a′ which fills the grooves G may be also irradiated with ultraviolet rays, a portion of the adhesive layer 40a′ may fill the grooves G as shown in FIG. 18.

According to the embodiment described above, a display apparatus and method of manufacturing the same in which the possibility of occurrence of defects in a manufacturing operation thereof may be reduced may be implemented. The scope of the disclosure is not limited by these effects.

It should be understood that embodiments described herein should be considered in a descriptive sense only and not for purposes of limitation. Descriptions of features or aspects in each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a display element;
an optical functional layer disposed on the display panel; and
a light control layer disposed on the optical functional layer, wherein
the light control layer comprises a plurality of grooves,
the plurality of grooves are respectively arranged adjacent to vertexes of the light control layer in a plan view,
sides of the light control layer respectively overlap sides of the optical functional layer in a plan view, and
in a plan view, the vertexes of the light control layer respectively overlap vertexes of the optical functional layer.

2. The display apparatus of claim 1, wherein,
in a plan view, the sides of the light control layer respectively coincide with the sides of the optical functional layer, and
in a plan view, the vertexes of the light control layer respectively coincide with the vertexes of the optical functional layer.

3. The display apparatus of claim 1, wherein
the optical functional layer comprises a first-1 side, a first-2 side, a first-3 side, and a first-4 side, the first-1 side and the first-2 side facing each other, and the first-3 side and the first-4 side facing each other and being positioned between the first-1 side and the first-2 side,
the light control layer comprises a second-1 side, a second-2 side, a second-3 side, and a second-4 side, the second-1 side and the second-2 side facing each other, and the second-3 side and the second-4 side facing each other and being positioned between the second-1 side and the second-2 side,
the second-1 side coincides with the first-1 side in a plan view,
the second-2 side coincides with the first-2 side in a plan view,
the second-3 side coincides with the first-3 side in a plan view, and
the second-4 side coincides with the first-4 side in a plan view.

4. The display apparatus of claim 3, wherein
the optical functional layer comprises a first-1 vertex provided by contact between the first-1 side and the first-3 side, a first-2 vertex provided by contact between the first-1 side and the first-4 side, a first-3 vertex provided by contact between the first-2 side and the first-3 side, and a first-4 vertex provided by contact between the first-2 side and the first-4 side,
the light control layer comprises a second-1 vertex provided by contact between the second-1 side and the second-3 side, a second-2 vertex provided by contact between the second-1 side and the second-4 side, a second-3 vertex provided by contact between the second-2 side and the second-3 side, and a second-4 vertex provided by contact between the second-2 side and the second-4 side,
the second-1 vertex coincides with the first-1 vertex in a plan view,
the second-2 vertex coincides with the first-2 vertex in a plan view,
the second-3 vertex coincides with the first-3 vertex in a plan view, and
the second-4 vertex coincides with the first-4 vertex in a plan view.

5. The display apparatus of claim 1, wherein
the light control layer further comprises a plurality of trenches, and
the plurality of trenches are respectively arranged between the plurality of grooves in a plan view.

6. The display apparatus of claim 5, wherein each of the plurality of trenches extends along one of the sides of the light control layer.

7. The display apparatus of claim 1, further comprising:
a control dam arranged in each of the plurality of grooves.

8. The display apparatus of claim 7, wherein the control dam and the light control layer are integral with each other.

9. The display apparatus of claim 1, further comprising:
a cover window disposed over the display panel; and
an adhesive layer disposed between the light control layer and the cover window.

10. The display apparatus of claim 9, wherein
the light control layer further comprises a plurality of trenches,
the plurality of trenches are respectively arranged between ones of the plurality of grooves in a plan view, and
the adhesive layer fills in the plurality of trenches.

11. The display apparatus of claim 1, wherein the optical functional layer comprises a polarizing film.

12. A method of manufacturing a display apparatus, the method comprising:
attaching an optical functional layer to a display panel;
attaching a light control layer to the optical functional layer;
forming a preliminary adhesive layer by applying an adhesive layer formation material to the light control layer and irradiating the adhesive layer formation material with ultraviolet rays;
arranging a cover window on the preliminary adhesive layer and pressurizing the cover window; and
forming an adhesive layer by irradiating ultraviolet rays to the preliminary adhesive layer, wherein
the light control layer comprises a plurality of grooves,
the plurality of grooves are respectively arranged adjacent to vertexes of the light control layer in a plan view,
the attaching of the light control layer comprises attaching the light control layer to the optical functional layer by using the plurality of grooves so that sides of the light control layer respectively overlap sides of the optical functional layer, and
the vertexes of the light control layer respectively overlap vertexes of the optical functional layer in a plan view.

13. The method of claim 12, wherein the attaching of the light control layer comprises attaching the light control layer to the optical functional layer by using the plurality of grooves so that the sides of the light control layer respectively coincide with the sides of the optical functional layer, and the vertexes of the light control layer respectively coincide with the vertexes of the optical functional layer in a plan view.

14. The method of claim 12, wherein
the optical functional layer comprises a first-1 side, a first-2 side, a first-3 side, and a first-4 side, the first-1 side and the first-2 side facing each other, and the first-3 side and the first-4 side facing each other and being positioned between the first-1 side and the first-2 side,
the light control layer comprises a second-1 side, a second-2 side, a second-3 side, and a second-4 side, the second-1 side and the second-2 side facing each other, and the second-3 side and the second-4 side facing each other and being positioned between the second-1 side and the second-2 side, and
the attaching of the light control layer comprises attaching the light control layer to the optical functional layer by using the plurality of grooves so that the second-1 side coincides with the first-1 side in a plan view, the second-2 side coincides with the first-2 side in a plan view, the second-3 side coincides with the first-3 side in a plan view, and the second-4 side coincides with the first-4 side in a plan view.

15. The method of claim 14, wherein
the optical functional layer comprises a first-1 vertex provided by contact between the first-1 side and the first-3 side, a first-2 vertex provided by contact between the first-1 side and the first-4 side, a first-3 vertex provided by contact between the first-2 side and the first-3 side, and a first-4 vertex provided by contact between the first-2 side and the first-4 side,
the light control layer comprises a second-1 vertex provided by contact between the second-1 side and the second-3 side, a second-2 vertex provided by contact between the second-1 side and the second-4 side, a second-3 vertex provided by contact between the second-2 side and the second-3 side, and a second-4 vertex provided by contact between the second-2 side and the second-4 side, and
the attaching of the light control layer comprises attaching the light control layer to the optical functional layer by using the plurality of grooves so that the second-1 vertex coincides with the first-1 vertex in a plan view, the second-2 vertex coincides with the first-2 vertex in a plan view, the second-3 vertex coincides with the first-3 vertex in a plan view, and the second-4 vertex coincides with the first-4 vertex in a plan view.

16. The method of claim 12, wherein
the light control layer further comprises a plurality of trenches,
the plurality of trenches are respectively arranged between ones of the plurality of grooves in a plan view, and
the forming of the preliminary adhesive layer comprises filling the adhesive layer formation material in the plurality of trenches.

17. The method of claim 16, wherein each of the plurality of trenches extends along one of the sides of the light control layer.

18. The method of claim 12, wherein
a control dam is arranged in each of the plurality of grooves, and
the forming of the preliminary adhesive layer comprises filling the adhesive layer formation material in the plurality of grooves.

19. The method of claim 18, wherein the control dam and the light control layer are integral with each other.

20. The method of claim 12, wherein the optical functional layer comprises a polarizing film.
